(19) United States
(12) Patent Application Publication
(10) Pub. No.: US 2025/0089378 A1
(43) Pub. Date: Mar. 13, 2025

(54) ELECTROSTATIC DISCHARGE PROTECTION CIRCUIT AND METHODS OF FORMING THE SAME

(71) Applicant: GlobalFoundries U.S. Inc., Malta, NY (US)

(72) Inventors: ALAIN F. LOISEAU, Williston, VT (US); ANINDYA NATH, Greenbelt, MD (US); MENG MIAO, Williston, VT (US); WEI LIANG, Burlington, VT (US); SOUVICK MITRA, Essex Junction, VT (US); ROBERT JOHN GAUTHIER, JR., Williston, VT (US)

(21) Appl. No.: 18/463,288

(22) Filed: Sep. 7, 2023

(51) Int. Cl. H01L 27/02; H01L 29/87

(52) U.S. Cl. CPC H10D 89/60; H10D 8/80

(57) ABSTRACT

An electrostatic discharge (ESD) protection circuit includes a silicon controlled rectifier. The silicon controlled rectifier includes a first well of a first conductivity type in a substrate, and a first doped region of a second conductivity type and a first tap region of the first conductivity type in the first well. The second conductivity type has an opposite polarity to the first conductivity type. The first doped region is coupled to a first pad. The first tap region is coupled to a second pad through a resistor external to the silicon controlled rectifier.

### TECHNICAL FIELD

The present disclosure relates generally to integrated circuits, and more particularly to an electrostatic discharge protection circuit and methods of forming the same.

### BACKGROUND

An electrostatic discharge protection (ESD) event refers to a phenomenon of electrical discharge of a current (positive or negative) for a short duration during which a large amount of current is provided to an integrated circuit (IC). To protect ICs from an ESD event, an ESD protection circuit may employ a silicon controlled rectifier (SCR) in the IC. An SCR, for example, may be implemented as a shunt to conduct high current discharges associated with an ESD event to ground and away from the circuitry of the IC. ESD SCRs may be used on high speed input/output (I/O) applications. However, the capacitances of the SCR may impact I/O operation. Therefore, it is desirable to have an improved ESD protection circuit and methods of forming thereof.

### SUMMARY

Embodiments generally relate to integrated circuits and methods of forming thereof. According to various embodiments, an electrostatic discharge (ESD) protection circuit is provided. The ESD protection circuit may include a silicon controlled rectifier. The silicon controlled rectifier may include a first well of a first conductivity type in a substrate, and a first doped region of a second conductivity type and a first tap region of the first conductivity type in the first well. The second conductivity type may have an opposite polarity to the first conductivity type. The first doped region is coupled to a first pad. The first tap region is coupled to a second pad through a resistor external to the silicon controlled rectifier.

According to another aspect, an ESD protection circuit may include a substrate, and a silicon controlled rectifier including a first well of a first conductivity type in the substrate, and a first doped region of a second conductivity type and a first tap region of the first conductivity type in the first well. The second conductivity type may have an opposite polarity to the first conductivity type. The first doped region is coupled to an input/output pad. The ESD protection circuit may further include an external resistor adjacent to the silicon controlled rectifier. The resistor may be arranged over the substrate. The first tap region may be coupled to a power pad through the resistor.

According to various embodiments, a method of forming a device is provided. The method may include providing a substrate prepared with a silicon controlled rectifier. The silicon controlled rectifier may include a first well of a first conductivity type in the substrate, and a first doped region of a second conductivity type and a first tap region of the first conductivity type in the first well. The method may further include coupling the first doped region to a first pad, and coupling the first tap region to a second pad through a resistor external to the silicon controlled rectifier.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following:

FIG. 1A illustrates a schematic of an embodiment of an ESD protection circuit or device;

FIGS. 1B-1C illustrate exemplary cross-sectional views of embodiments of the ESD protection circuit or device;

FIG. 1D illustrates exemplary cross-sectional view of an embodiment of the ESD protection circuit;

FIG. 2A illustrates a schematic of another embodiment of an ESD protection circuit;

FIG. 2B illustrates another exemplary cross-sectional view of an embodiment of the ESD protection circuit;

FIG. 3 illustrates a schematic of yet another embodiment of an ESD protection circuit; and

FIG. 4 shows an exemplary flow diagram of a process for forming a device.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the embodiments. Other embodiments may be utilized and structural, logical, and electrical changes may be made without departing from the scope of the invention. The various embodiments are not necessarily mutually exclusive, as some embodiments can be combined with one or more other embodiments to form new embodiments.

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

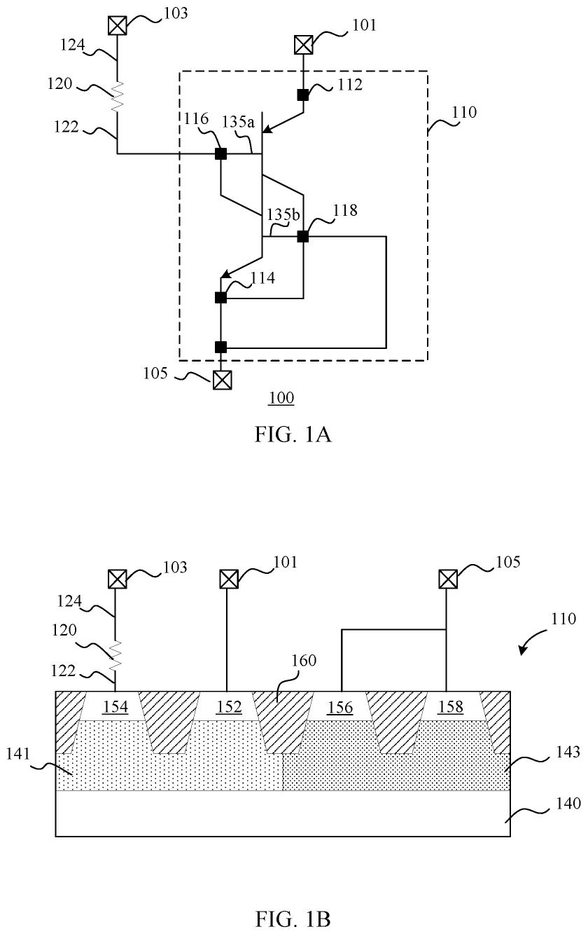

FIG. 1A illustrates a schematic of an embodiment of an ESD protection circuit or device 100. The ESD protection circuit 100 may be a portion of an integrated circuit (IC) and may be for protecting a circuitry of the IC, for example, during an ESD event. The ESD protection circuit 100 may include a silicon controlled rectifier (SCR) 110 having an anode 112 coupled to a first pad 101 and a cathode 114 coupled to a third pad 105. The first pad 101, for example, may be an input/output (I/O) pad of the IC. The I/O pad may be coupled to the IC circuitry. The third pad 105 may be coupled to ground or reference voltage Vₛₛ of the IC. In one embodiment, the SCR 110 may be further coupled to a second pad 103 through a resistor 120. The first pad 101 and the second pad 103 may be different pads. In one embodiment, the second pad 103 may be a power pad such as a voltage supply V_{dd}. A first node 116 includes a first gate 135a of the SCR 110 and a first resistor terminal 122 of the resistor 120. A second node 118 may include a second gate 135b of the SCR 110. The second node 118 may be coupled to the third pad 105.

The resistor 120 may be an element external to the SCR 110 (e.g., external resistor). The resistor 120 is external to the SCR 110, since the resistor 120 does not have any structural components that are integrated with (or shared by) the structural components of the SCR 110. The resistor 120 is not part of the SCR's internal resistance. The resistor 120 may have the first resistor terminal 122 coupled to the first gate 135a of the SCR 110 and a second resistor terminal 124 coupled to the second pad 103. In one embodiment, the SCR 110 and resistor 120 together serve as an ESD protection circuit 100 for the circuitry of an integrated circuit (IC). When turned on, the SCR 110 may function as a shunt to redirect any ESD currents from the first pad 101, through the anode 112 and the cathode 114 of the SCR 110, to ground (third pad 105).

FIG. 1B illustrates exemplary components of the SCR 110 of the ESD protection circuit 100 of FIG. 1A. FIG. 1C illustrates exemplary components of the resistor 120 of the ESD protection circuit 100 of FIG. 1A.

Referring to FIG. 1B, the SCR 110 may be formed in a substrate 140. The substrate 140 may be a semiconductor substrate, such as a silicon substrate. Other types of substrates, such as silicon germanium, germanium, gallium arsenide, or crystal-on-insulator (COI) such as silicon-on-insulator (SOI), may also be used. In one embodiment, the substrate 140 may be lightly doped, for example, with a dopant of a second conductivity type. A first well 141 of a first conductivity type and a second well 143 of the second conductivity type may be arranged in the substrate 140. The first conductivity type may have an opposite polarity to the second conductivity type. In one embodiment, the first conductivity type may be n-type while the second conductivity type may be p-type. The first well 141 and the second well 143 may be lightly or intermediately doped with dopants. The first well 141 and the second well 143 may abut each other.

A first doped region 152 and a first tap region (which may also be referred to herein as first body contact) 154 may be arranged in the first well 141. The first doped region 152 may have the opposite conductivity type from the first well 141. The first tap region 154 may have the same conductivity type as the first well 141. In one embodiment, the first doped region 152 may be of the second conductivity type and the first tap region 154 may be of the first conductivity type. The first doped region 152 may form the anode 112 of the SCR 110 and may be coupled to the first pad 101. The first tap region 154 may form the first gate 135a of the SCR 110. The first tap region 154 may be coupled to the second pad 103 through the resistor 120. As described, the first pad 101 and the second pad 103 may be different pads. The first pad 101 may be an input/output pad and the second pad 103 may be a power pad.

A second doped region 156 and a second tap region (which may also be referred to herein as second body contact) 158 may be arranged in the second well 143. The second doped region 156 may have the opposite conductivity type from the second well 143. The second tap region 158 may have the same conductivity type as the second well 143. In one embodiment, the second doped region 156 may be of the first conductivity type and the second tap region 158 may be of the second conductivity type. The second doped region 156 may form the cathode 114 of the SCR 110 and may be coupled to the third pad 105. The second tap region 158 may form the second gate 135b of the SCR 110. The second tap region 158 may be coupled to the third pad 105.

The first doped region 152, the second doped region 156, the first tap region 154 and the second tap region 158 may be heavily doped regions. For example, a dopant concentration for lightly doped may be about 10¹⁶ cm⁻³ or less, while a dopant concentration for heavily doped may be about 10¹⁸ cm⁻³ or greater.

In one embodiment, isolation regions 160 may be provided in the substrate 140. The isolation regions 160, for example, may be shallow trench isolation regions. The isolation regions 160 may be formed of a dielectric material such as silicon dioxide. Other types of isolation regions may also be useful. The isolation regions 160 may separate the doped regions 152 and 156 and tap regions 154 and 158. The isolation regions 160 may have a depth deeper than the doped regions 152 and 156 and tap regions 154 and 158.

As described, the resistor 120 may be an external resistor with respect to the SCR 110. In one embodiment, the resistor 120 may be arranged over the substrate 140, as illustrated in FIG. 1C. In one embodiment, the resistor 120 may be arranged in the interlevel dielectric over the substrate 140. For example, the resistor 120 may be arranged in a dedicated level of a BEOL metallization structure (not shown). Arranging the resistor 120 in a dedicated level of the BEOL metallization structure may allow a larger area for the resistor, and accordingly provide a larger sheet resistance. In one embodiment, the resistor 120 may be arranged on an isolation region 160a in the substrate 140. The isolation region 160a, for example, may be a shallow trench isolation region disposed in the substrate 140.

In one embodiment, the resistor 120 may include a layer of resistive material 171. For example, the layer of resistive material 171 may be polysilicon. The resistor 120, for example, may be a polysilicon resistor. For example, the resistor 120 may be a silicided polysilicon resistor, unsilicided polysilicon resistor, unsalicided polysilicon resistor, or salicided polysilicon resistor. In one embodiment, the resistor 120 is an unsilicided polysilicon resistor. The resistor 120 may have a resistance value ranging between about 10 k ohms to about 1 G ohms. The resistor 120 may include a silicide layer 173. The resistor 120 may be coupled to the first tap region 154 in the first well 141 of the SCR 110 and the second pad 103 using interconnects 175. The interconnects 175 may include contacts and wiring formed in the interlevel dielectric in the BEOL process. For example, the interconnects may be formed of a conductive material such as copper, copper alloy, aluminum, tungsten or a combination thereof. Other suitable types of metal, alloys or conductive materials may also be useful. A silicide block layer 177 may be arranged over the layer of resistive material 171. The silicide block layer 177, for example, may be formed of dielectric material such as nitride. The silicide block layer 177 may be used to block silicide formation over a portion of the layer of resistive material 171.

FIG. 1D illustrates an exemplary cross-sectional view of an embodiment of the ESD protection circuit. In one embodiment, the resistor 120 may be arranged adjacent to the SCR 110. A third well 145 of the second conductivity type (e.g., P-well) may be adjacent to the first well 141. The isolation region 160a may be arranged adjacent to the SCR 110. As illustrated, the layer of resistive material 171 and silicide block layer 177 may be arranged over the isolation region 160a. In one embodiment, the first tap region 154 may be coupled to the resistor 120 using interconnect 180. The interconnect 180 may include contacts and wiring formed in the interlevel dielectric (or metallization structure) in the back-end-of-line (BEOL) process to connect the first tap region 154 and the resistor 120. The first tap region 154 may be connected to the resistor 120 using the interconnect 180 without any other intervening elements or components therebetween. The first doped region 152 is not directly coupled to the resistor 120.

Accordingly, various embodiments provide an ESD protection circuit with the SCR 110 having the first well 141 (e.g., N-well) coupled to the second pad 103 through the resistor 120 which may reduce capacitance of the SCR 110 compared to conventional ESD SCR circuits which may have large capacitances from the PN junction between the P+ doped region (anode in the N-well) and the N-well and between the N-well and P-well of the SCR. In the case that the resistance value of the resistor 120 is 0 ohm, the first well 141 (e.g., N-well) may be biased at direct current (DC) voltage and the capacitance of the SCR 110 may be from the reversed biased PN junction between the first doped region 152 (e.g., P+ doped region) and the first well 141 (e.g., N-well). The capacitance from the junction between the first doped region 152 and the first well 141 may be reduced due to the reverse biasing. A higher supply voltage V_{dd} from the second pad 103 may reduce the capacitance of the SCR 110 due to a larger depletion region. In the case that the resistance value of the resistor 120 is infinite, the first well 141 (e.g., N-well) may be floating. The capacitance from the PN junction between the first doped region 152 and the first well 141 may be in series with the capacitance from the PN junction between the first well 141 and the second well 143, which reduces the capacitance of the SCR 110. In one embodiment, coupling the first tap region 154/the first well 141 to the voltage source at second pad 103 through the resistor 120 having a predetermined resistance value, R, may advantageously reduce capacitance of the SCR 110 significantly compared to the scenario where the resistance value of the resistor 120 is 0 ohm or infinite. The predetermined resistance value, R may range between about 10 k ohms to about 1 G ohms. In another embodiment, the predetermined resistance value, R may range between about 10 k ohms to about 1 M ohms. The predetermined resistance value, R may establish DC biasing on the first tap region 154 (the first well 141 may be biased at DC voltage) while retaining AC swing on the first tap region 154. The first well 141 may be semi-floating through the resistor 120.

The ESD protection circuit 100 may operate as a breakdown SCR. The SCR 110 may be triggered based on breakdown of the junction between the first well 141 and the second well 143. The ESD protection circuit 100 may operate in a first or a second operating mode. The first operating mode, for example, is a normal operating mode while the second mode is an ESD mode. During normal operation, the supply voltage V_{dd} at the second pad 103 may be selected so that the junction between the first doped region 152 and the first well 141 is reversed biased. For example, the supply voltage V_{dd} may be about 1.8V, 2.5V. 3.3V or 5V to reverse bias the junction between the first doped region 152 and the first well 141. The current on the first pad 101 (e.g., I/O pad) of SCR 110 may only be the leakage of the reversed biased junction between first doped region 152 and the first well 141. During the ESD mode, there may be a current path between the first pad 101 (I/O pad) and the third pad 105 (ground). For example, current dissipates through the substrate 140 of the device, preventing damage to the internal circuit or other circuits coupled to the first pad 101. By coupling the first well 141/the first tap region 154 to the second pad 103 which may be the power source V_{dd}, instead of coupling to the first pad 101 which may be the I/O pad, the full I/O voltage is not directly applied to the first well 141/the first tap region 154 in the ESD mode. The trigger voltage may be increased by one diode drop.

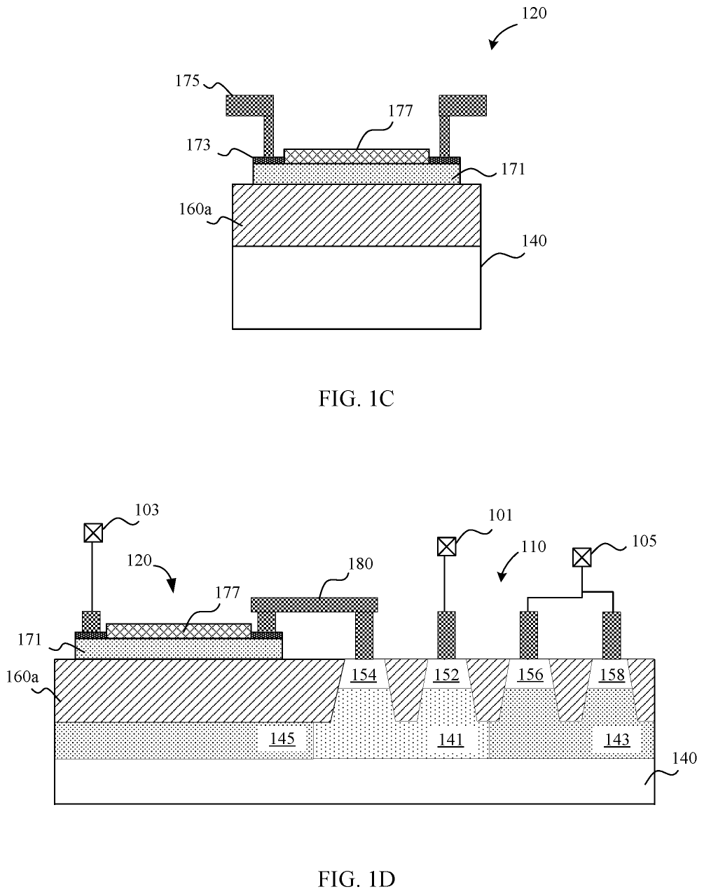

FIG. 2A illustrates a schematic of another embodiment of an ESD protection circuit or device 200. The ESD protection circuit 200 may be a portion of an integrated circuit (IC) and may be for protecting a circuitry of the IC, for example, during an ESD event.

Referring to FIG. 2A, the ESD protection circuit 200 may be similar to the ESD protection circuit 100, but may include a trigger device 230 configured to trigger the SCR 110. The trigger device 230 may have a first terminal 232 coupled to the first gate 135a of the SCR 110 and to the first resistor terminal 122, and a second terminal 234 coupled to the cathode 114 of the SCR 110. The trigger device 230 may include diodes coupled in series. As illustrated in FIG. 2A, the trigger device 230 may include diodes serially coupled in a forward conduction direction from the first gate 135a of the SCR 110 (e.g., the first tap region 154) to the cathode 114 of the SCR 110 (the second doped region 156). In this configuration, the leakage current from the second pad 103 may be increased, but the leakage current from the first pad 101 may be reduced as the first pad 101 is coupled to the reversed biased junction formed by the first doped region 152 and the first well 141.

FIG. 2B shows an exemplary cross-sectional view of an embodiment of the ESD protection circuit or device 200 of FIG. 2A. More particularly, FIG. 2B illustrates the SCR 110 coupled to the trigger device 230. Referring to FIG. 2B, the ESD protection circuit 200 may be similar to the ESD protection circuit 100 in FIG. 1B, but may include the trigger device 230 configured to trigger the SCR 110. The trigger device 230 may include trigger diodes. As illustrated in FIG. 2B, a fourth well 242 and a fifth well 244 may be arranged in the substrate 140. The fourth well 242 and the fifth well 244 may be of the first conductivity type (e.g., N-wells). A third well 245 of the second conductivity type may be arranged between the first well 141 and the fourth well 242, and a sixth well 246 of the second conductivity type may be arranged between the fourth well 242 and the fifth well 244. Highly doped regions 251 and 252 of the second conductivity type (e.g., p-type doped regions) may be arranged in the fourth well 242 and the fifth well 244, respectively. Highly doped regions 253 and 254 of the first conductivity type (e.g., n-type doped regions) may be arranged in the fourth well 242 and the fifth well 244, respectively. For example, the trigger device 230 may be two P+ doped region/N-well diodes. The isolation regions 160 may separate the highly doped regions. The doped region 251, for example, may serve as the first terminal 232 of the trigger device 230, while the doped region 254 may serve as the second terminal 234 of the trigger device 230. The first tap region 154 of the SCR 110 may be coupled to the doped region 251 of the trigger device 230 using interconnect 280.

In one embodiment, the ESD protection circuit 200 may operate as a diode triggered SCR. The SCR 110 may be triggered by the trigger device 230. The ESD protection circuit 200 may operate in a normal operating mode or in an ESD mode. During normal operation, the supply voltage V_{dd} at the second pad 103 may be selected so that the junction between the first doped region 152 and the first well 141 is reversed biased. The supply voltage V_{dd} at the second pad 103 may be chosen to be higher than the I/O voltage at the first pad 101. The capacitance of the SCR 110 may be lower when the supply voltage V_{dd} at the second pad 103 is higher than the I/O voltage at the first pad 101. For example, the supply voltage V_{dd} may be about 0.8 V. 1.0 V. 1.2 V. 1.5 V or 1.8 V. There may be leakage current from the voltage supply at the second pad 103 through resistor 120 and the diodes of the trigger device 230, however the forward diode I/O leakage current from the first pad 101 may be reduced or eliminated for the ESD protection circuit 200. The trigger current of the SCR 110 may range from about 1 mA to about 10 mA. The resistor 120 may have a resistance value such that a negligible fraction of current goes through it during the ESD mode.

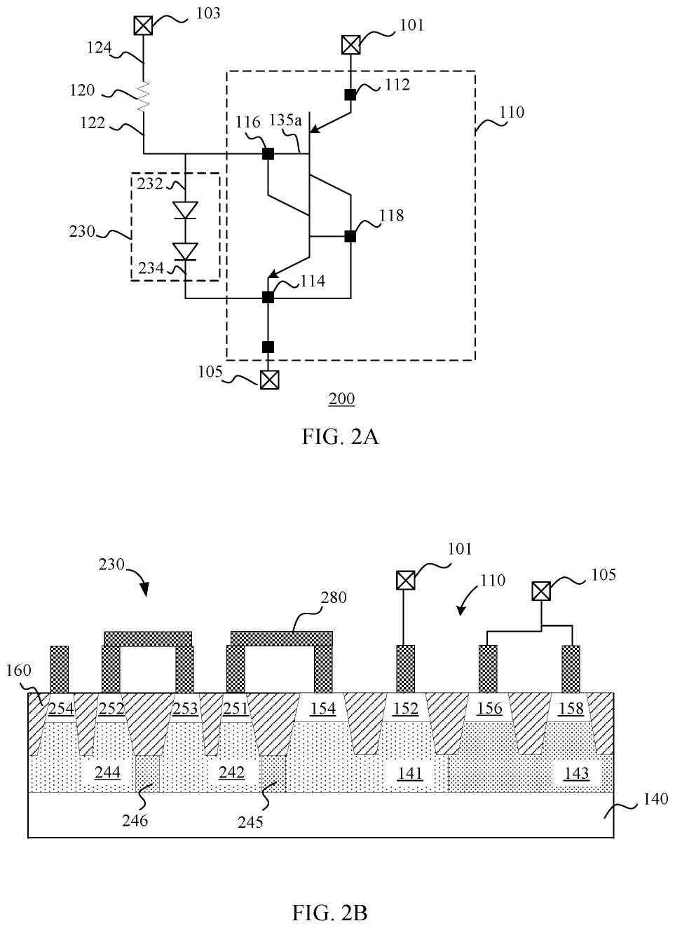

In one embodiment, the SCR 110 may be further coupled to the resistor 120 through a diode 332 to reduce the leakage current from the supply voltage V_{dd} at the second pad 103, as illustrated in FIG. 3. FIG. 3 illustrates the first node 116 of the SCR 110 includes the first gate 135a of the SCR 110 and a terminal of the diode 332. The first tap region 154 which serves as the first gate 135a of the SCR 110 is coupled to the second pad 103 through the diode 332 and the resistor 120. The first doped region 152 may be coupled to the terminal of the diode 332 using interconnects in the BEOL metallization structure (not shown).

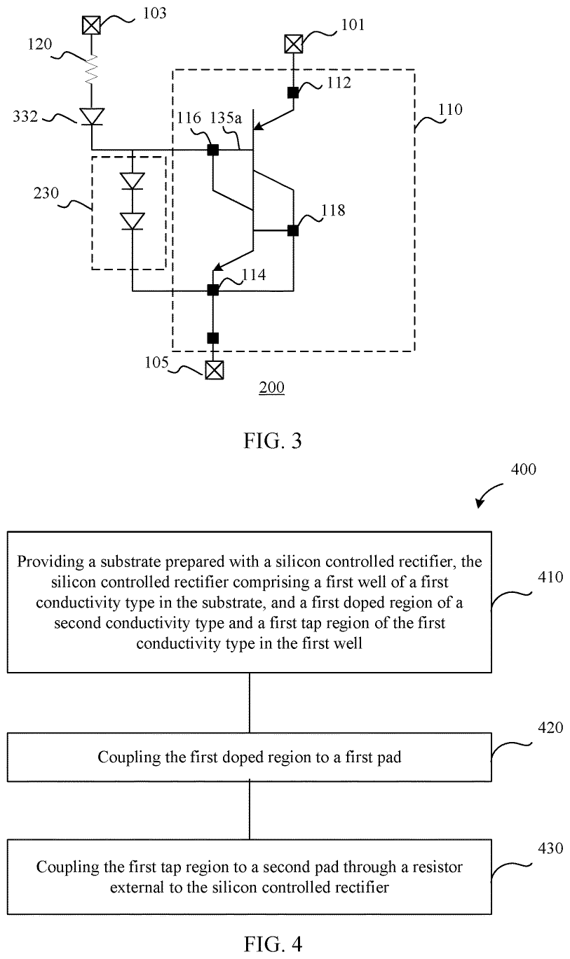

FIG. 4 shows an exemplary flow diagram of a process or method 400 for forming a device. The device may be an ESD protection circuit. The device, for example, is similar to that described in FIGS. 1A-1D, 2 and 3. As such, common elements may not be described or described in detail.

At 410, a substrate prepared with a silicon controlled rectifier may be provided. The silicon controlled rectifier may include a first well of a first conductivity type in the substrate, and a first doped region of a second conductivity type and a first tap region of the first conductivity type in the first well.

At 420, the first doped region may be coupled to a first pad. For example, the first doped region may be coupled to the first pad using interconnects in the BEOL metallization structure.

At 430, the first tap region may be coupled to a second pad through a resistor external to the silicon controlled rectifier. For example, the resistor may be connected to the first tap region and the second pad using interconnects in the BEOL metallization layers. The first pad and the second pad may be different pads. The first pad may be an input/output pad and the second pad may be a power pad.

According to various embodiments, the method 400 may arrange the resistor adjacent to the SCR. The resistor may be arranged over the substrate. In one embodiment, the substrate may include an isolation region adjacent to the SCR in the substrate, and arranging the resistor over the substrate may include forming the resistor on the isolation region. Forming the resistor may include forming a layer of resistive material on the isolation region, forming a silicide block layer on the layer of resistive material and forming a silicide layer in regions on the layer of resistive material not covered by the silicide block layer.

Additional processes may be performed to complete fabrication of the device. Such processes may include forming additional interconnections and/or elements, final passivation, dicing, packaging, testing, etc.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. An electrostatic discharge (ESD) protection circuit, comprising:
a silicon controlled rectifier comprising a first well of a first conductivity type in a substrate, and a first doped region of a second conductivity type and a first tap region of the first conductivity type in the first well, the second conductivity type having an opposite polarity to the first conductivity type,
wherein the first doped region is coupled to a first pad, and the first tap region is coupled to a second pad through a resistor external to the silicon controlled rectifier.

2. The ESD protection circuit of claim 1, wherein the first pad is an input/output pad and the second pad is a power pad.

3. The ESD protection circuit of claim 1, further comprising a second well of the second conductivity type adjacent to the first well, and a second tap region of the second conductivity type in the second well, wherein the second tap region is coupled to ground.

4. The ESD protection circuit of claim 3, further comprising a second doped region of the first conductivity type in the second well, the second doped region is coupled to ground, wherein the first doped region forms an anode and the second doped region forms a cathode of the silicon controlled rectifier.

5. The ESD protection circuit of claim 1, wherein the resistor has a resistance value between about 10 k ohms to about 1 G ohms.

6. The ESD protection circuit of claim 1, wherein the resistor is adjacent to the silicon controlled rectifier and arranged over the substrate.

7. The ESD protection circuit of claim 1, further comprising an isolation region adjacent to the silicon controlled rectifier in the substrate, wherein the resistor is arranged on the isolation region.

8. The ESD protection circuit of claim 1, wherein the first conductivity type is n-type and the second conductivity type is p-type.

9. The ESD protection circuit of claim 1, wherein the resistor comprises a silicide block layer on a layer of resistive material.

10. The ESD protection circuit of claim 9, wherein the layer of resistive material comprises polysilicon.

11. The ESD protection circuit of claim 1, further comprising a trigger device configured to trigger the silicon controlled rectifier, wherein the first tap region of the silicon controlled rectifier is further coupled to a first terminal of the trigger device.

12. The ESD protection circuit of claim 11, wherein the first tap region is further coupled to the second pad through a diode connected to the resistor.

13. An electrostatic discharge (ESD) protection circuit, comprising:
a substrate;
a silicon controlled rectifier comprising a first well of a first conductivity type in the substrate, and a first doped region of a second conductivity type and a first tap region of the first conductivity type in the first well, the second conductivity type having an opposite polarity to the first conductivity type, wherein the first doped region is coupled to an input/output pad; and
an external resistor adjacent to the silicon controlled rectifier, the resistor is arranged over the substrate, wherein the first tap region is coupled to a power pad through the resistor.

14. The ESD protection circuit of claim 13, wherein the resistor has a resistance value between about 10 k ohms to about 1 G ohms.

15. The ESD protection circuit of claim 13, further comprising a second well of the second conductivity adjacent to the first well, a second tap region of the second conductivity type and a second doped region of the first conductivity type in the second well, wherein the second tap region and the second doped region are coupled to ground.

16. A method of forming a device, comprising:
providing a substrate prepared with a silicon controlled rectifier, the silicon controlled rectifier including a first well of a first conductivity type in the substrate, and a first doped region of a second conductivity type and a first tap region of the first conductivity type in the first well;
coupling the first doped region to a first pad; and
coupling the first tap region to a second pad through a resistor external to the silicon controlled rectifier.

17. The method of claim 16, wherein the first pad is an input/output pad and the second pad is a power pad.

18. The method of claim 16, wherein the resistor is arranged over the substrate.

19. The method of claim 16, wherein the substrate comprises an isolation region adjacent to the silicon controlled rectifier in the substrate, and further comprising forming the resistor on the isolation region.

20. The method of claim 19, wherein forming the resistor comprises forming a layer of resistive material on the isolation region and forming a silicide block layer on the layer of resistive material.
